(19) United States
(12) Patent Application Publication
(10) Pub. No.: US 2024/0153765 A1
(43) Pub. Date: May 9, 2024

(54) METHOD AND APPARATUS FOR PRODUCING GROUP III NITRIDE SEMICONDUCTOR

(71) Applicants: SCREEN Holdings Co., Ltd., Kyoto (JP); National University Corporation Tokai National Higher Education and Research System, Nagoya-shi, Aichi (JP)

(72) Inventors: Masaki INABA, Kyoto-shi, Kyoto (JP); Kei SUZUKI, Kyoto-shi, Kyoto (JP); Masaru HORI, Nagoya-shi, Aichi (JP); Osamu ODA, Nagoya-shi, Aichi (JP); Kazuki KODAMA, Nagoya-shi, Aichi (JP)

(21) Appl. No.: 18/280,621

(22) PCT Filed: Mar. 9, 2022
(86) PCT No.: PCT/JP2022/010344

§ 371 Date: Sep. 6, 2023

(30) Foreign Application Priority Data
Mar. 11, 2021 (JP) 2021-039226

(51) Int. Cl. H01L 21/02; C23C 16/30; H01L 21/263; H01L 21/67

(52) U.S. Cl. CPC H01L 21/0254; C23C 16/303; H01L 21/02252; H01L 21/0242; H01L 21/2636; H01L 21/67017; H01L 21/67115

(57) ABSTRACT

A method for producing a group III nitride semiconductor includes a loading step (S1), a decompression step (S2), a heating step (S3), an excitation gas supply step (S5), and an organometallic gas supply step (S6). In the loading step (Si), a substrate is loaded into a chamber. In the decompression step (S2), a suction part reduces a pressure inside the chamber. In the heating step (S3), a heater provided inside the chamber heats the substrate. In the excitation gas supply step (S5), a first gas that contains nitrogen without containing hydrogen is supplied to a plasma generator, and an excitation gas obtained by turning the first gas into plasma by the plasma generator is supplied to the substrate inside the chamber. In the organometallic gas supply step (S6), a second gas that is an organometallic gas that contains a group III element is supplied to the substrate inside the chamber.

### TECHNICAL FIELD

The present application relates to a method and an apparatus for producing a group III nitride semiconductor.

### BACKGROUND ART

Conventionally, a technique of forming a gallium nitride (GaN) film on a substrate by an organometallic vapor phase growth method has been proposed. In the organometallic vapor phase growth method, generally, a substrate is heated in the vicinity of atmospheric pressure, an organometallic gas (for example, trimethylgallium) as a gallium source and an ammonia (NH₃) gas as a nitrogen source are supplied to the substrate, and a gallium nitride film is grown on the substrate with gallium and nitrogen generated by thermal decomposition.

In such a producing method, it is necessary to thermally decompose ammonia gas, and a high temperature of 1100° C. or higher is required for the thermal decomposition. When the temperature increases, the substrate is stressed by heat, and there is a high possibility that a crack occurs in the film. This leads to a decrease in device yield.

Therefore, an organometallic vapor phase growth method using plasma has been proposed (for example, Patent Document 1). In a producing apparatus described in Patent Document 1, an organometallic gas of a group III element is supplied into a chamber while a mixed gas of a nitrogen (N₂) gas and a hydrogen (H₂) gas is turned into plasma inside the chamber. According to this, since there is no need to thermally decompose an ammonia gas as a nitrogen source, a group III nitride semiconductor film can be formed on a substrate at a relatively low temperature.

### PRIOR ART DOCUMENT

### Patent Document

Patent Document 1: Japanese Patent No. 6516482

### SUMMARY

### Problem to be Solved by the Invention

In the technique described in Patent Document 1, while the group III nitride semiconductor film can be formed at a low temperature, there is a problem that more carbon is taken into the semiconductor film as the temperature decreases. When a carbon content in the semiconductor film increases, a bulk mobility of the semiconductor film decreases, and film quality decreases.

Therefore, an object of the present application is to provide a technique capable of producing a group III nitride semiconductor having a small carbon content.

### Means to Solve the Problem

A first aspect of a method for producing a group III nitride semiconductor is a method for producing a group III nitride semiconductor including: a loading step of loading a substrate into a chamber; a decompression step of reducing a pressure inside the chamber by a suction part; a heating step of heating the substrate by a heater provided inside the chamber; an excitation gas supply step of supplying an excitation gas to the substrate inside the chamber, the excitation gas being obtained by supplying a first gas that contains a nitrogen gas without containing a hydrogen gas to a plasma generator and turning the first gas into plasma by the plasma generator; and an organometallic gas supply step of supplying a second gas to the substrate inside the chamber, the second gas being an organometallic gas that contains a group III element.

A second aspect of the method for producing a group III nitride semiconductor is the method of producing a group III nitride semiconductor according to the first aspect, wherein a ratio of a density of nitrogen radicals to a flow rate of the second gas is 1 or more and 10 or less.

A third aspect of the method for producing a group III nitride semiconductor is the method for producing a group III nitride semiconductor according to the first or second aspect, wherein in the heating step, the substrate is heated to a temperature of 800° C. or higher and 1000° C. or lower.

A fourth aspect of the method for producing a group III nitride semiconductor is the method for producing a group III nitride semiconductor according to any one of the first to third aspects, wherein the second gas contains trimethylgallium, triethylgallium, or trisdimethylamidogallium.

A fifth aspect of the method for producing a group III nitride semiconductor is the method for producing a group III nitride semiconductor according to any one of the first to fourth aspects, wherein in the decompression step, the pressure inside the chamber is reduced to 100 Pa or more and 500 Pa or less.

A first aspect of an apparatus for producing a group III nitride semiconductor is an apparatus for producing a group III nitride semiconductor including: a chamber; a substrate holder that is provided inside the chamber and holds a substrate; a suction part that reduces a pressure inside the chamber; a heater that is provided inside the chamber and heats the substrate; a first gas supply part that supplies a first gas that contains a nitrogen gas without containing hydrogen; a plasma generator that supplies an excitation gas to the substrate inside the chamber, the excitation gas being generated by turning the first gas supplied from the first gas supply part into plasma; and a second gas supply part that supplies a second gas to the substrate inside the chamber, the second gas being an organometallic gas containing a group III element.

### Effects of the Invention

According to the method and the apparatus for producing a group III nitride semiconductor, since hydrogen is not turned into plasma, a reaction between the second gas and hydrogen can be suppressed, and generation of a methane-based compound can be suppressed. The methane-based compound is easily taken into the group III nitride semiconductor, and a carbon content in the semiconductor is increased, whereas the production of the methane-based compound can be suppressed, so that the carbon content in the semiconductor can be reduced. In other words, a group III nitride semiconductor having a small carbon content can be formed on the substrate.

### BRIEF DESCRIPTION OF DRAWINGS

FIG. 1 is a diagram schematically showing one example of a configuration of an apparatus for producing a group III nitride semiconductor.

FIG. 2 is a block diagram showing one example of an internal configuration of a control part.

FIG. 3 is a flowchart showing one example of a method for producing a group III nitride semiconductor.

FIG. 4 is a graph showing one example of a distribution of a concentration of carbon in a semiconductor film.

FIG. 5 is a graph showing one example of a distribution of a concentration of carbon in a semiconductor film according to a comparative example.

FIG. 6 is a graph showing one example of a relationship between a flow rate of a second gas and the concentration of carbon in the semiconductor film.

FIG. 7 is a graph showing one example of a relationship between a ratio of a density of nitrogen radicals to the flow rate of the second gas and the concentration of carbon in the semiconductor film.

### DESCRIPTION OF EMBODIMENT

Hereinafter, a preferred embodiment will be described with reference to the drawings. Note that components described in the present embodiment are merely examples, and the scope of the present disclosure is not intended to be limited thereto. In the drawings, dimensions or a number of parts may be exaggerated or simplified as necessary for easy understanding.

Each of expressions indicating relative or absolute positional relationships (for example, “in one direction”, “along one direction”, “parallel”, “orthogonal”, “center”, “concentric”, “coaxial”, and the like) not only strictly represents a positional relationship, but also represents a state of being relatively displaced with respect to an angles or a distance within a range in which a tolerance or a comparable function is obtained, unless otherwise specified. Each of expressions indicating equal states (for example, “same”, “equal”, “homogeneous”, and the like) not only represents a state that are quantitatively and strictly equal, but also represents a state in which there are a difference that allows a tolerance or a comparable function to be obtained, unless otherwise specified. Each of expressions indicating shapes (for example, “quadrangular”, “cylindrical”, and the like) not only represents a shape geometrically and strictly, but also represents a shape having, for example, unevenness or chamfering, or the like within a range in which a comparable effect can be obtained, unless otherwise specified. Each of expressions “comprising”, “provided with”, “including”, or “having” is not an exclusive expression that excludes presence of other components. An expression “at least any one of A, B, and C” includes only A, only B, only C, any two of A, B and C, and all of A, B and C.

<Outline of Producing Apparatus>

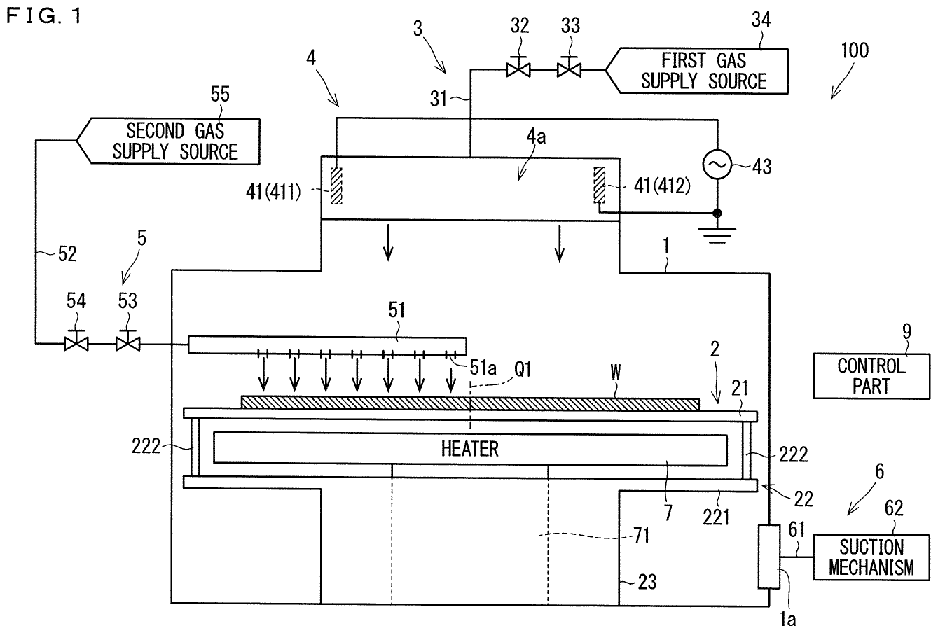

FIG. 1 is a diagram schematically showing one example of a configuration of an apparatus 100 for producing a group III nitride semiconductor. This producing apparatus 100 is a film forming apparatus that forms a group III nitride semiconductor film on a main surface of a substrate W by an organometallic vapor phase growth method using plasma. The substrate W is, for example, a substrate of sapphire or the like. The substrate W has, for example, a disk shape. Since the group III nitride semiconductor film is crystal-grown on the main surface of the substrate W, the substrate W is also called a growth substrate. Note that a material and a shape of the substrate W are not limited thereto, and can be appropriately changed.

The producing apparatus 100 includes a chamber 1, a substrate holder 2, a first gas supply part 3, a plasma generator 4, a second gas supply part 5, a suction part 6, a heater 7, and a control part 9. Hereinafter, each configuration will be outlined, and then a specific example thereof will be described in detail.

The chamber 1 has a box-shaped hollow shape. An internal space of the chamber 1 corresponds to a processing space for performing film formation processing on the substrate W. The chamber 1 may also be referred to as a vacuum chamber.

The substrate holder 2 is provided inside the chamber 1. The substrate holder 2 holds the substrate W in a horizontal posture. The horizontal posture here is a posture in which a thickness direction of the substrate W is along a vertical direction.

The suction part 6 sucks a gas inside the chamber 1 to reduce a pressure inside the chamber 1. The suction part 6 adjusts the pressure inside the chamber 1 within a predetermined decompression range suitable for the film formation processing.

The heater 7 is provided inside the chamber 1 and heats the substrate W. Specifically, the heater 7 heats the substrate W so that a temperature of the substrate W falls within a temperature range suitable for the film formation processing.

The first gas supply part 3 supplies a first gas to the plasma generator 4. The first gas is a gas containing nitrogen without containing hydrogen. The first gas may contain only a nitrogen gas.

The plasma generator 4 turns at least a part of the first gas into plasma. As a result, active species such as highly reactive nitrogen ions or neutral radicals are generated. Hereinafter, gas and plasma obtained by turning the first gas into plasma are also collectively referred to as an excitation gas. The excitation gas includes active species of nitrogen and a nitrogen gas. In the example of FIG. 1, the plasma generator 4 has a plasma chamber 4a, and the first gas is turned into plasma in the plasma chamber 4a. The excitation gas flows out of the plasma chamber 4a and flows toward the substrate W inside the chamber 1. As a result, the excitation gas is supplied to the substrate W inside the chamber 1.

The second gas supply part 5 supplies a second gas to the substrate W inside the chamber 1. The second gas is an organometallic gas containing a group III element. The group III element is also referred to as a group 13 element. The group III element is, for example, gallium, and in this case, TMG (trimethylgallium), TEG (triethylgallium), or TDMAG (trisdimethylamidogallium) can be adopted as the second gas.

The control part 9 integrally controls the entire producing apparatus 100. For example, the control part 9 controls the substrate holder 2, the first gas supply part 3, the plasma generator 4, the second gas supply part 5, the suction part 6, and the heater 7.

According to the producing apparatus 100, the plasma generator 4 turns the first gas into plasma to generate highly reactive nitrogen active species. This highly reactive nitrogen active species reacts with the group III element thermally decomposed from the second gas on an upper surface of the heated substrate W to form the group III nitride semiconductor film on the upper surface of the substrate W. When the group III element is gallium, a gallium nitride (GaN) film is formed as the group III nitride semiconductor film.

As described above, according to the producing apparatus 100, the group III nitride semiconductor film is formed using not only the chemical reaction by heat but also the highly reactive active species by plasmatization. Therefore, even if the temperature of the substrate W is lowered, the group III nitride semiconductor film can be formed on the upper surface of the substrate W. Therefore, a crack of the substrate can be suppressed, and a yield can be improved.

Moreover, according to the producing apparatus 100, the gas (first gas) to be turned into plasma does not contain hydrogen. As a result, as will be described in detail later, a carbon content in the group III nitride semiconductor film can be reduced. Therefore, a bulk mobility of the group III nitride semiconductor film can be improved, and film quality thereof can be improved.

Hereinafter, one specific example of each configuration and one example of specific operation of the producing apparatus 100 will be described in detail.

<Substrate Holder>

The substrate holder 2 holds the substrate W in a horizontal posture. In the example of FIG. 1, the substrate holder 2 includes a susceptor 21 and a susceptor holder 22. The susceptor 21 is a table for placing the substrate W, and has, for example, a flat plate shape. The susceptor 21 is provided in a horizontal posture, and the substrate W is placed on an upper surface of the susceptor 21 in the horizontal posture. The upper surface of the substrate W placed on the susceptor 21 is exposed inside the chamber 1.

The susceptor holder 22 is provided inside the chamber 1 and holds the susceptor 21. In the example of FIG. 1, the susceptor holder 22 includes a holding base 221 and holding protrusions 222. The holding base 221 is provided vertically below the susceptor 21, and faces the susceptor 21 at an interval in the vertical direction. The holding base 221 has, for example, a horizontal upper surface, and the holding protrusions 222 are erected on the upper surface. For example, a plurality of the holding protrusions 222 are provided and arranged along a peripheral portion of a lower surface of the susceptor 21. A distal end of each of the holding protrusions 222 is in contact with the susceptor 21 to support or hold the susceptor 21.

In the example of FIG. 1, the substrate holder 2 further includes a rotation mechanism 23. The rotation mechanism 23 rotates the susceptor holder 22 around a rotation axis Q1. The rotation axis Q1 is an axis passing through a central portion of the substrate W and extending along the vertical direction. The rotation mechanism 23 includes, for example, a shaft and a motor. An upper end of the shaft is connected to a lower surface of the holding base 221. The shaft extends along the rotation axis Q1 and is pivotally support in the chamber 1 rotatably around the rotation axis Q1. The motor rotates the shaft around the rotation axis Q1. As a result, the susceptor holder 22, the susceptor 21, and the substrate W rotate integrally around the rotation axis Q1.

<Heater>

The heater 7 heats the substrate W held by the substrate holder 2 inside the chamber 1. In the example of FIG. 1, the heater 7 is provided vertically below the susceptor 21, and faces the susceptor 21 at an interval in the vertical direction. In the example of FIG. 1, the heater 7 is provided between the susceptor 21 and the holding base 221 on a radially inner side of the holding protrusions 222. The heater 7 may be, for example, an electric resistance type heater including an electric heating wire, or may be an optical type heater including a light source that emits light for heating.

Here, the heater 7 is provided so as not to rotate around the rotation axis Q1. That is, the heater 7 does not rotate. For example, the shaft of the rotation mechanism 23 is a hollow shaft, and the heater 7 is fixed to the chamber 1 via a fixing member 71 penetrating the hollow portion.

<Suction Part>

The suction part 6 sucks the gas inside the chamber 1. In the example of FIG. 1, the suction part 6 includes a suction pipe 61 and a suction mechanism 62. An upstream end of the suction pipe 61 is connected to an exhaust port 1a of the chamber 1. In the example of FIG. 1, the exhaust port 1a is formed vertically below the substrate W held by the substrate holder 2, and is formed, for example, on a side wall of the chamber 1. The suction mechanism 62 is, for example, a pump (more specifically, a vacuum pump), and is connected to the suction pipe 61. The suction mechanism 62 is controlled by the control part 9 and sucks the gas inside the chamber 1 through the suction pipe 61.

<First Gas Supply Part>

The first gas supply part 3 supplies the first gas to the plasma generator 4 (more specifically, the plasma chamber 4a). In the example of FIG. 1, the first gas supply part 3 includes a supply pipe 31, a valve 32, and a flow rate adjusting part 33. A downstream end of the supply pipe 31 is connected to the plasma generator 4, and an upstream end thereof is connected to a first gas supply source 34. The first gas supply source 34 supplies the first gas to the upstream end of the supply pipe 31.

The valve 32 is interposed in the supply pipe 31. The valve 32 is controlled by the control part 9, and opening of the valve 32 allows the first gas to be supplied from the first gas supply source 34 to the plasma generator 4 through the supply pipe 31. Closing of the valve 32 stops the supply of the first gas.

The flow rate adjusting part 33 is interposed in the supply pipe 31. The flow rate adjusting part 33 is controlled by the control part 9, and adjusts a flow rate of the first gas flowing through the supply pipe 31. The flow rate adjusting part 33 is, for example, a mass flow controller.

<Plasma Generator>

The plasma generator 4 turns the first gas supplied from the first gas supply part 3 into plasma. In the example of FIG. 1, the plasma generator 4 is provided on a ceiling portion of the chamber 1. The plasma generator 4 includes conductive members 41 and a power supply for plasma 43. The conductive members 41 are provided inside the plasma chamber 4a, and the power supply for plasma 43 is electrically connected to the conductive members 41. The power supply for plasma 43 is controlled by the control part 9, and applies a voltage for plasma (for example, a high-frequency voltage) to the conductive members 41. As a result, an electric field (or magnetic field) for generating plasma is formed around the conductive members 41.

In the example of FIG. 1, an electrode 411 and an electrode 412 are illustrated as the conductive members 41. The electrode 411 and the electrode 412 are provided to face each other at an interval in the horizontal direction. The power supply for plasma 43 is electrically connected to the electrode 411 and the electrode 412, and applies the voltage for plasma generation between the electrode 411 and the electrode 412. The power supply for plasma 43 outputs, for example, a high-frequency voltage between the electrode 411 and the electrode 412. As a result, the electric field for plasma generation is generated in the space between the electrode 411 and the electrode 412.

In the example of FIG. 1, the downstream end of the supply pipe 31 of the first gas supply part 3 is connected to an upper portion of the plasma chamber 4a. Since the first gas supplied from the supply pipe 31 flows vertically downward between the electrode 411 and the electrode 412 inside the plasma chamber 4a, the electric field for plasma is applied to the first gas between the electrode 411 and the electrode 412. As a result, at least a part of the first gas is turned into plasma, and active species of nitrogen are generated. The excitation gas containing the active species of nitrogen flows out vertically downward from the plasma chamber 4a and flows toward the substrate W.

Note that in the example of FIG. 1, the plasma generator 4 generates plasma by a so-called capacitive coupling method, but may generate plasma by an inductive coupling method.

<Second Gas Supply Part>

The second gas supply part 5 supplies the second gas into the chamber 1. In the example of FIG. 1, the second gas supply part 5 includes a discharge nozzle 51, a supply pipe 52, a valve 53, and a flow rate adjusting part 54. The discharge nozzle 51 is provided inside the chamber 1. In the example of FIG. 1, the discharge nozzle 51 is provided vertically below the plasma generator 4 and vertically above the substrate holder 2, and discharges the second gas toward the substrate W held by the substrate holder 2. In the example of FIG. 1, the discharge nozzle 51 has an elongated shape extending horizontally, and faces the substrate holder 2 in the vertical direction. The discharge nozzle 51 extends, for example, along a radial direction of the substrate W in plan view. In other words, a longitudinal direction of the discharge nozzle 51 is along the radial direction of the substrate W. In the example of FIG. 1, the discharge nozzle 51 is provided such that a distal end of the discharge nozzle 51 faces the central portion of the substrate W in the vertical direction.

Discharge ports 51a are formed in the discharge nozzle 51. In the example of FIG. 1, a plurality of discharge ports 51a are arranged at intervals along the longitudinal direction of the discharge nozzle 51. The plurality of discharge ports 51a are provided at positions facing the substrate W in the vertical direction, and the second gas is discharged from each of the discharge ports 51a toward the upper surface of the substrate W.

Since the second gas flows toward the substrate holder 2 on the side opposite to the plasma generator 4, the electric field (or magnetic field) of the plasma generator 4 is hardly applied to the second gas. In other words, the discharge nozzle 51 is provided away from the plasma generator 4 by a distance at which the electric field (or magnetic field) of the plasma generator 4 is not substantially applied. Therefore, the second gas is not substantially turned into plasma.

The discharge nozzle 51 is connected to a second gas supply source 55 via the supply pipe 52. That is, a downstream end of the supply pipe 52 is connected to an upstream end of the discharge nozzle 51, and an upstream end of the supply pipe 52 is connected to the second gas supply source 55. The second gas supply source 55 supplies the second gas to the upstream end of the supply pipe 52.

The valve 53 is interposed in the supply pipe 52 and is controlled by the control part 9. Opening of the valve 53 allows the second gas to be supplied from the second gas supply source 55 into the chamber 1 through the supply pipe 52 and the discharge nozzle 51. Closing of the valve 53 stops the supply of the second gas.

The flow rate adjusting part 54 is interposed in the supply pipe 52. The flow rate adjusting part 54 is controlled by the control part 9, and adjusts a flow rate of the second gas flowing through the supply pipe 52. The flow rate adjusting part 54 is, for example, a mass flow controller.

<Control Part>

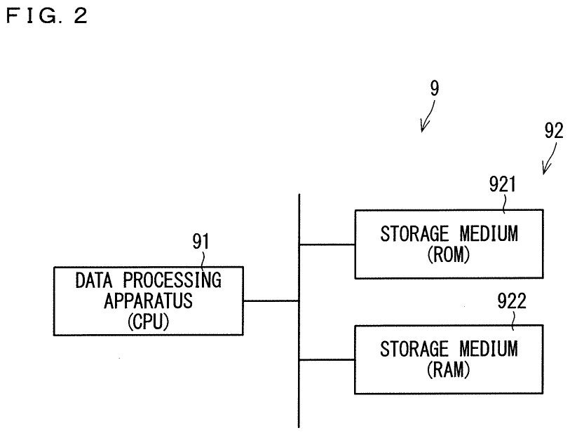

FIG. 2 is a block diagram schematically showing one example of a configuration of the control part 9. The control part 9 is electronic circuit equipment, and may have, for example, a data processing apparatus 91 and a storage medium 92. The data processing apparatus 91 may be, for example, an arithmetic processing apparatus such as a central processor unit (CPU). The storage medium 92 may have a non-transitory storage medium 921 (for example, a read only memory (ROM) or a hard disk) and a transitory storage medium 922 (for example, a random access memory (RAM)). The non-transitory storage medium 921 may store, for example, a program that defines processing to be executed by the control part 9. When the data processing apparatus 91 executes this program, the control part 9 can execute the processing defined in the program. Of course, part or all of the processing executed by the control part 9 may be executed by a hardware circuit such as a logic circuit.

<Operation of Apparatus for Producing Group III Nitride Semiconductor>

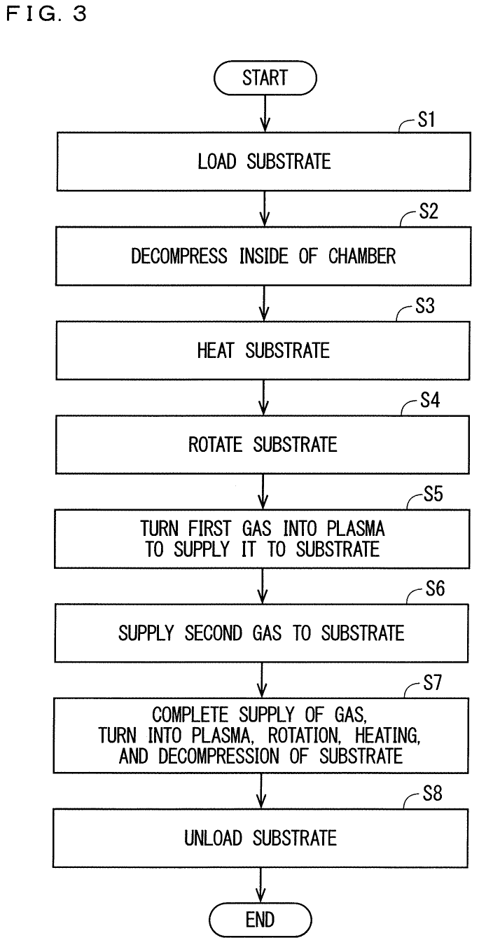

Next, one example of operation of the apparatus 100 for producing a group III nitride semiconductor will be described. FIG. 3 is a flowchart showing one example of the operation of the apparatus 100 for producing a group III nitride semiconductor. In other words, FIG. 3 is a flowchart showing one example of a method for producing a group III nitride semiconductor.

First, the substrate W is conveyed into the chamber 1 by a conveyance apparatus (not shown) (step S1: loading step).

Next, the suction part 6 sucks the gas inside the chamber 1 to reduce the pressure inside the chamber 1 (step S2: decompression step). Specifically, the control part 9 causes the suction mechanism 62 to perform suction operation. As a result, the gas inside the chamber 1 is sucked by the suction mechanism 62 through the suction pipe 61, and the pressure inside the chamber 1 is reduced. The suction part 6 adjusts the pressure inside the chamber 1 so that the pressure inside the chamber 1 becomes a predetermined process pressure suitable for the film formation processing. The predetermined process pressure is, for example, 100 Pa or more and 500 Pa or less. The suction part 6 adjusts the pressure inside the chamber 1 until the film formation processing is completed.

Next, the heater 7 heats the substrate W (step S3: heating step). Specifically, the control part 9 causes the heater 7 to perform heating operation. The heater 7 adjust the temperature of the substrate W so that the temperature of the substrate W becomes a predetermined temperature suitable for the film formation processing. The predetermined temperature is, for example, 800° C. or higher and 1000° C. or lower. The heater 7 adjusts the temperature of the substrate W until the film formation processing is completed.

Next, the substrate holder 2 rotates the substrate W around the rotation axis Q1 (step S4: rotation step). Specifically, the control part 9 causes the rotation mechanism 23 to rotate the susceptor holder 22. As a result, the susceptor holder 22, the susceptor 21, and the substrate W rotate integrally around the rotation axis Q1. The substrate holder 2 rotates the substrate W until the film formation processing is completed.

Next, the first gas supply part 3 supplies the first gas to the plasma generator 4, and the plasma generator 4 supplies the substrate W inside the chamber 1 with the excitation gas generated by turning the first gas into plasma (step S5: excitation gas supply step). Specifically, first, the control part 9 opens the valve 32. As a result, the first gas is supplied from the first gas supply source 34 to the plasma generator 4 through the supply pipe 31, passes through the plasma generator 4, and flows toward the substrate W inside the chamber 1. Here, the first gas is a nitrogen gas. The first gas supply part 3 supplies the nitrogen gas until the film formation processing is completed.

Then, the control part 9 causes the power supply for plasma 43 to output the high-frequency voltage. As a result, the electric field for plasma is generated in the space between the electrode 411 and the electrode 412. When the nitrogen gas passes through the electric field, at least a part thereof is turned into plasma. By the change of the nitrogen gas into plasma, active species of nitrogen are generated, and the excitation gas containing the active species flows out of the plasma chamber 4a and flows toward the upper surface of the substrate W inside the chamber 1. The plasma generator 4 turns the nitrogen gas into plasma until the film formation processing is completed.

Next, the second gas supply part 5 supplies the second gas into the chamber 1 (step S6: organometallic gas supply step). For example, the second gas supply part 5 starts supplying the second gas in a state where the plasma generated by the plasma generator 4 is stable. Specifically, the control part 9 opens the valve 53. As a result, the second gas is supplied from the second gas supply source 55 into the chamber 1 through the supply pipe 52 and the discharge nozzle 51, and flows toward the upper surface of the substrate W. Here, the second gas is TMG, TEG, or TDMAG.

The second gas is thermally decomposed on the upper surface of the substrate W, and the group III element generated by the thermal decomposition reacts with the active species of nitrogen, whereby the group III nitride semiconductor film is crystal-grown on the upper surface of the substrate W. Of the gas supplied to the upper surface of the substrate W, a substance that has not contributed to the formation of the group III nitride semiconductor film is discharged to an outside from the exhaust port 1a.

Here, since the substrate holder 2 rotates the substrate W around the rotation axis Q1, the group III nitride semiconductor film can be more uniformly formed on the upper surface of the substrate W.

When the group III nitride semiconductor film having a predetermined thickness is formed on the upper surface of the substrate W, the supply of the first gas and the second gas, the output of the high-frequency voltage (that is, plasma change), the rotation of the substrate W, the heating of the substrate W, and the decompression inside the chamber 1 are completed in order to substantially complete the film formation processing (step S7).

Next, the conveyance apparatus unloads the substrate W from the chamber 1 (step S8: unloading step). For example, the conveyance apparatus unloads the substrate W placed on the susceptor 21 from the chamber 1.

As described above, according to the producing apparatus 100, the active species of nitrogen and the organometallic gas (second gas) containing the group III element react with each other on the upper surface of the substrate W to form the group III nitride semiconductor film on the upper surface of the substrate W. That is, since energy (plasma) other than heat is utilized in the film formation processing, the group III nitride semiconductor film can be formed on the upper surface of the substrate W even when the temperature of the substrate W is a relatively low temperature of 1000° C. or less.

Moreover, according to the producing apparatus 100, the first gas to be turned into plasma does not contain hydrogen. Therefore, it is possible to suppress generation of a methane-based compound due to the reaction between hydrogen and the second gas (organometallic gas). Although methane is easily taken into the group III nitride semiconductor, carbon into the group III nitride semiconductor film can be restrained from being taken by suppressing the production of methane. That is, the group III nitride semiconductor film having a small carbon content can be formed on the substrate W. Therefore, the group III nitride semiconductor film having a high bulk mobility and excellent film quality can be formed on the substrate W.

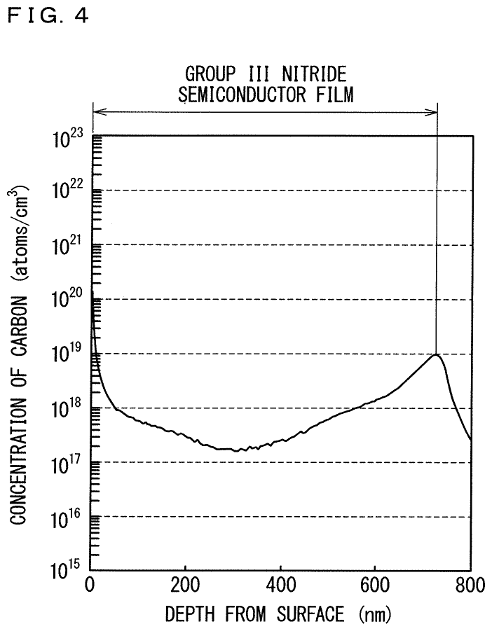

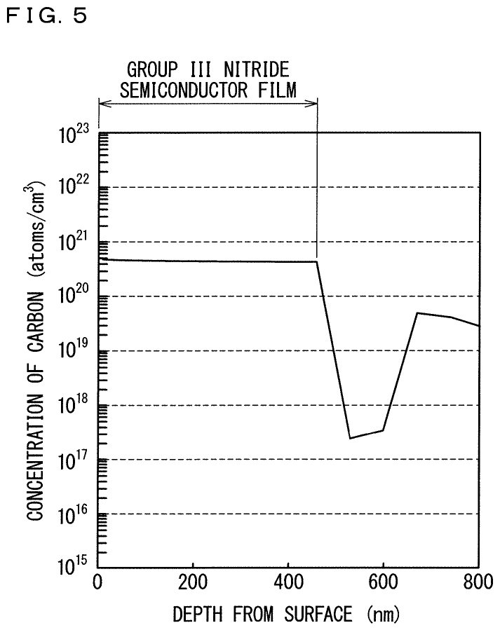

FIGS. 4 and 5 are graphs each showing one example of an experimental result, and each show a concentration distribution of carbon in the group III nitride semiconductor film obtained by secondary ion mass spectrometry. A horizontal axis indicates a depth from a surface of the group III nitride semiconductor film, and zero indicates the surface of the semiconductor film. A vertical axis indicates the concentration of carbon in the group III nitride semiconductor film. FIG. 4 shows an experimental result in a case only a nitrogen gas is adopted as the first gas not containing hydrogen, and FIG. 5 shows an experimental result when a mixed gas of a nitrogen gas and a hydrogen gas is adopted instead of the first gas as a comparative example. That is, FIG. 5 shows the experimental result when the mixed gas of the nitrogen gas and the hydrogen gas is supplied to the plasma generator 4 and the plasma generator 4 turns the mixed gas into plasma. In FIG. 4, a flow rate of the nitrogen gas was 2000 sccm, and in FIG. 5, flow rates of the nitrogen gas and the hydrogen gas were 1900 sccm and 100 sccm, respectively.

As can be understood from the comparison between FIGS. 4 and 5, when the first gas containing no hydrogen is supplied, the concentration of carbon can be reduced by one digit or more as compared with the case where the mixed gas of the hydrogen gas and the nitrogen gas is supplied. Therefore, the bulk mobility of the group III nitride semiconductor film can be improved, and the film quality thereof can be improved.

<Supply Amount of Active Species of Nitrogen and Second Gas (Organometallic Gas)>

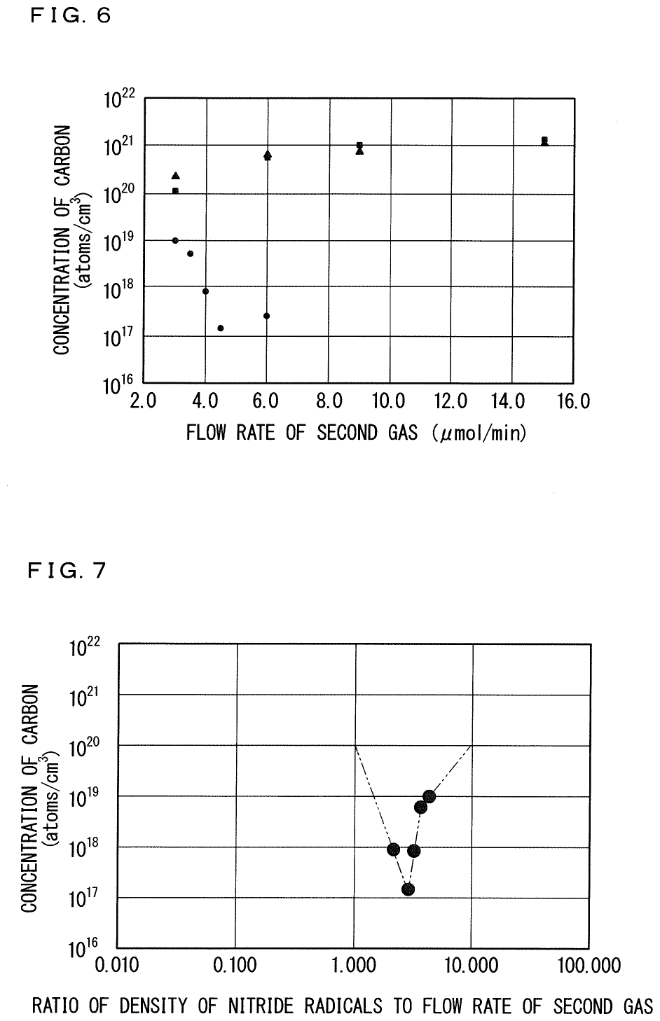

Next, a relationship between the flow rate of the second gas and the concentration of carbon in the group III nitride semiconductor film will be considered. FIG. 6 is a graph showing the relationship between the flow rate of the second gas and the concentration of carbon. Here, an experimental result in a case where only a nitrogen gas is supplied as the first gas at a flow rate of 2000 sccm is indicated by black circle plotted points. In addition, as a comparative example, experimental results in a case where a nitrogen gas and a hydrogen gas are supplied at flow rates of 1900 sccm and 100 sccm, respectively are indicated by black triangle plot points, and experimental results in a case where the nitrogen gas and the hydrogen gas are supplied at flow rates of 1950 sccm and 50 sccm are indicated by black square plot points.

As can be understood from FIG. 6, in the case where the mixed gas of the nitrogen gas and the hydrogen gas is supplied instead of the first gas, the concentration of carbon increases as the flow rate of the second gas (organometallic gas) increases. On the other hand, in the case where the nitrogen gas not containing hydrogen is turned into plasma, the concentration of carbon temporarily decreases as the flow rate of the second gas (organometallic gas) increases, and the concentration of carbon increases as the flow rate of the second gas further increases. That is, the concentration of carbon has a downward convex waveform with respect to the flow rate of the second gas.

Such finding is disclosed for the first time by the present application. According to this finding, it is found that in the case where the first gas to be turned into plasma does not contain hydrogen, there is a preferable range of the flow rate of the second gas, unlike the case where the gas to be turned into plasma contains hydrogen gas. That is, it is found that the flow rate of the second gas has a more preferable flow rate range for reducing the carbon content in the group III nitride semiconductor film.

By the way, since the group III nitride semiconductor film is formed by the reaction between the active species (radicals) of nitrogen and the second gas, it is necessary to consider not only the flow rate of the second gas but also the nitrogen radicals. Therefore, a ratio of a density (number/cm 3) of nitrogen radicals to the flow rate (μmol/min) of the second gas is introduced. The ratio is considered to have a preferred range for reducing the carbon content.

FIG. 7 is a graph showing a relationship between the ratio of the density of nitrogen radicals to the flow rate of the second gas and the concentration of carbon in the group III nitride semiconductor film. Note that the density of nitrogen radicals was measured at a position above the upper surface of the substrate W by 1 cm.

As shown in FIG. 7, when the ratio increases, the concentration of carbon temporarily decreases, and when the ratio further increases, the concentration of carbon increases. That is, the concentration of carbon also has a downward convex waveform with respect to the ratio. As described above, a reason why the concentration of carbon turns from a decrease to an increase is considered as follows. That is, when the density of the nitrogen radicals exceeds a certain critical value (about 4) with respect to the flow rate of the second gas, crystal growth partially occurs in a three-dimensional direction on the upper surface of the substrate W, and irregularities are formed on the upper surface of the substrate W. As a result, a surface area of the semiconductor film increases, and a carbon adsorption site on the surface increases. Therefore, it is considered that more carbon is adsorbed on the adsorption site, and as a result, the concentration of carbon in the semiconductor film increases.

As shown in FIG. 7, the concentration of carbon also has a downward convex waveform with respect to the ratio, and it can be seen that there is a preferable ratio range for reducing the concentration of carbon in the ratio. Here, as an index of the concentration of carbon for determining the preferred ratio range, the concentration of carbon when the mixed gas of the hydrogen gas and the nitrogen gas is supplied is adopted. As can be understood from FIG. 6, when the mixed gas of the hydrogen gas and the nitrogen gas is supplied, the concentration of carbon in the group III nitride semiconductor film is larger than 10²⁰. Therefore, 10²⁰ can be adopted as the index.

Referring to FIG. 7, in order to set the concentration of carbon to 10²⁰ or less, it is desirable that the ratio is 1 or more and 10 or less. That is, it is desirable that the control part 9 controls the flow rate of the first gas through the flow rate adjusting part 33, the flow rate of the second gas through the flow rate adjusting part 54, and the output voltage of the power supply for plasma 43 so that the ratio is 1 or more and 10 or less.

In addition, in a plot point group of FIG. 7, a minimum value and a maximum value of the ratio are about 2 and 6, respectively. Therefore, it is more desirable that the control part 9 controls the flow rate of the first gas through the flow rate adjusting part 33, the flow rate of the second gas through the flow rate adjusting part 54, and the output voltage of the power supply for plasma 43 so that the ratio is 2 or more and 6 or less.

<Temperature of Substrate>

In the above example, the heater 7 heats the substrate W so that the temperature of the substrate W is 800° C. or higher and 1000° C. or lower. In this temperature range, a production amount of the methane-based compound easily taken into the group III nitride semiconductor was small, and the carbon content of the group III nitride semiconductor could be effectively reduced.

As described above, the apparatus 100 and the method for producing a group III nitride semiconductor have been described in detail, but the above description is illustrative in all aspects, and the producing apparatus 100 and the producing method are not limited thereto. It is understood that innumerable modifications not illustrated can be envisaged without departing from the scope of the present disclosure. The configurations described in the above embodiment and modifications can be appropriately combined or omitted as long as they do not contradict each other.

### EXPLANATION OF REFERENCE SIGNS

1: chamber
2: substrate holder
3: first gas supply part
4: plasma generator
5: second gas supply part
6: suction part
7: heater
S1: loading step
S2: decompression step
S3: heating step
S5: first gas supply step
S6: plasma processing step
S7: second gas supply step
W: substrate

1. A method for producing a group III nitride semiconductor, the method comprising:
a loading step of loading a substrate into a chamber;
a decompression step of reducing a pressure inside said chamber by a suction part;
a heating step of heating said substrate by a heater provided inside said chamber;
an excitation gas supply step of supplying an excitation gas to said substrate inside said chamber the excitation gas being obtained by supplying a first gas that contains a nitrogen gas without containing hydrogen to a plasma generator and turning said first gas into plasma by said plasma generator; and
an organometallic gas supply step of supplying a second gas to said substrate inside said chamber, the second gas being an organometallic gas containing a group III element.

2. The method for producing a group III nitride semiconductor according to claim 1, wherein a ratio of a density of nitrogen radicals to a flow rate of said second gas is 1 or more and 10 or less.

3. The method for producing a group III nitride semiconductor according to claim 1, wherein in said heating step, the substrate is heated to a temperature of 800° C. or higher and 1000° C. or lower.

4. The method for producing a group III nitride semiconductor according to claim 1, wherein said second gas contains trimethylgallium, triethylgallium, or trisdimethylamidogallium.

5. The method for producing a group III nitride semiconductor according to claim 1, wherein in said decompression step, the pressure inside said chamber is reduced to 100 Pa or more and 500 Pa or less.

6. An apparatus for producing a group III nitride semiconductor, the apparatus comprising:
a chamber;
a substrate holder that is provided inside said chamber and holds a substrate;
a suction part that reduces a pressure inside said chamber;
a heater that is provided inside said chamber and heats said substrate;
a first gas supply part that supplies a first gas that contains a nitrogen gas without containing hydrogen;
a plasma generator that supplies an excitation gas to said substrate inside said chamber, the excitation gas being generated by turning said first gas supplied from said first gas supply part into plasma; and
a second gas supply part that supplies a second gas to said substrate inside said chamber, the second gas being an organometallic gas that contains a group III element.
